(19) United States
(12) Patent Application Publication
(10) Pub. No.: US 2026/0282853 A1
(43) Pub. Date: Sep. 17, 2026

(54) METHOD FOR SURFACE TREATMENT OF A SUBSTRATE AND METHOD FOR BONDING SUCH A SUBSTRATE TO A FURTHER SUBSTRATE, AND A DEVICE FOR CARRYING OUT SUCH METHODS

(71) Applicant: EV Group E. Thallner GmbH, ST. FLORIAN AM INN (AT)

(72) Inventor: Peter KEREPESI, ST. FLORIAN AM INN (AT)

(21) Appl. No.: 19/163,709

(22) PCT Filed: Mar. 21, 2023
(86) PCT No.: PCT/EP2023/057183

§ 371 Date: Sep. 9, 2025

(51) Int. Cl. H10P 95/00; H10P 10/00

(52) U.S. Cl. CPC H10P 95/02; H10P 10/128

(57) ABSTRACT

A method for surface treatment of a substrate (B), in particular as a preparatory step for a method for bonding the substrate to a further substrate, including: —providing the substrate (B) having a bonding surface provided for the bonding, —treating (100) the substrate (B) at least in a portion of the bonding surface to form an amorphous layer (C) having a first thickness (D1), a primary particle radiation preferably being used for forming the amorphous layer (C), and —reducing (200) the layer thickness of the amorphous layer (C), preferably to a second thickness (D2).

### CROSS-REFERENCE TO RELATED APPLICATIONS

This application is a 35 U.S.C. § 371 National Stage patent application of PCT/EP2023/057183 filed 21 Mar. 2023, the disclosure of which is incorporated herein by reference in its entirety.

### BACKGROUND

The present invention relates to a method for surface treatment of a substrate and a method for bonding the substrate to another substrate and an apparatus for performing such methods.

In the semiconductor industry, different bonding technologies have been used for several years to join substrates together. The bonding process is called bonding. A distinction is made between temporary bonding processes and permanent bonding processes. In fusion bonding, for example, two plane, pure substrate surfaces are bonded by contacting. In a first step, the two substrates are contacted, wherein the two substrates are pre-fixed by Van der Waals forces. In order to create a permanent fusion bond, the substrate stacks are subjected to heat treatment.

In order to be able to bond at low temperatures, a plasma treatment for cleaning and activating at least one of the substrate surfaces can be performed prior to fusion bonding.

In U.S. Pat. No. 10,312,217 B2, the substrate surfaces are pre-treated at room temperature prior to bonding to improve the bond strength. For this purpose, a bond layer is deposited on the substrate surfaces, planarized by chemical-mechanical polishing and modified by plasma etching. The activation of the surface is performed by RIE plasma processes or by reactions with reactive gases or liquids, so that the activated surface consists of an activated oxygen or an activated nitrogen compound.

US 2021/0 225 803 A1 discloses systems that enable a combination of a wet chemical processes and a vacuum-based processes for the pretreatment of substrates prior to bonding at the lowest possible temperatures. In US 2021/0 225 803A1, the passivating oxide layers are removed largely without the formation of amorphous layers or the implantation of particles on the substrate surfaces. For this purpose, a low-energy plasma is used in a plasma chamber in combination with a series of previously performed wet chemical processes for the treatment of the substrate surfaces.

In U.S. Pat. No. 10,985,204 B2, a low-energy plasma is used to remove surface oxides. The formation of an amorphous layer is not desired. In U.S. Pat. No. 10,985,204 B2, an implantation of low energy hydrogen is additionally performed in the surfaces to be bonded. Possible existing local defects, which could lead to a higher electrical resistance at the bonding interface after bonding of the substrates at temperatures below 300° C., are passivated with the implanted hydrogen during the subsequent heat treatment.

For example, in U.S. Pat. No. 10,312,217 B2, an additional bond layer is applied, which is additionally activated using physical and/or (wet) chemical methods. US 202 1/0 225 803 A1 also discloses systems that enable a combination of wet chemical and vacuum-based processes for the pretreatment of substrates prior to bonding at the lowest possible temperatures. In U.S. Pat. No. 10,985,204 B2, an implantation of low energy hydrogen into the surfaces to be bonded is additionally performed.

Ion beam processes are another method for modifying substrate surfaces prior to bonding. The accelerated ions hit the substrate material to be modified at the end of their trajectory.

A conventional ion gun comprises a source of charged particles that are accelerated by an externally applied electrical field created between a pair of grids. Conventionally, three grids are used for the production of low energy ion beams. Different grid arrangements can be used, the potentials of which are individually controlled. In a multi-grid system, the first grid on which the ions impinge is usually positively biased and the second grid negatively biased. A further grid can be used to slow down the ions leaving the ion source so that a collimated beam of ions with more or less uniform power is created.

More preferably, oxide removal is performed on materials where an oxygen-containing atmosphere forms a natural oxide before bonding substrate surfaces. However, this does not apply to created oxygen substrate surfaces, such as silicon oxide. In particular, preferably at least predominantly, more preferably exclusively, harmful, unnecessary and/or natural, in particular metallic, oxides are removed. Preferably, the aforementioned oxides are removed as far as possible, in particular completely, before a bonding process, so as not to be incorporated into the bonding interface (contact surface of two substrates). The incorporation of such oxides would lead to mechanical destabilization and a very low bond strength. The oxide is removed in particular by physical and/or chemical methods.

Pre-treatment also changes the micro-roughness of the substrate surfaces and maximum bonding energies can be achieved if optimum surface roughness is achieved. This allows spontaneous, covalent bonds to form at low temperatures, especially at room temperature. Contact is made in a high vacuum.

EP 3 161 855 B1 describes a method and apparatus for the surface treatment of substrates. The basic idea of EP 3 161 855 B1 is to create a predominantly amorphized layer on a substrate surface to be bonded. In EP 3 161 855 B1, the amorphization of the substrate surfaces leads to a better bonding result, in particular at comparatively low temperatures. More preferably, the surface is cleaned to remove oxides and amorphized at the same time.

In the prior art, the formation of an amorphous surface layer due to phase transformation of the substrate material during pretreatment of substrate surfaces prior to bonding is undesirable. If an amorphous layer is formed in the prior art, it is not applied by transforming the substrate material itself, but by depositing an additional amorphous layer on the substrate surfaces by chemical and/or physical deposition processes.

In order to prevent possible damage or to achieve a better bonding force at room temperature, further process steps are necessary in the prior art.

EP 3 161 85 5B1 relates in particular to a method for permanently bonding two substrates, at least one of which, preferably both, is treated prior to bonding. In the process, surface areas, in particular a contact side, preferably the entire surface, of both or at least one of the two substrates are amorphized before the bonding process. The amorphization creates a nanometer-thick layer in which the atoms of at least one of the surfaces to be bonded are arranged randomly. To create a bond according to the invention, the surfaces are cleaned, in particular to remove oxides. An essential aspect of EP 3 161 855 B1 is in particular the use of energetic particles, in particular ions, to effect amorphization.

In EP 3 161 855 B1, an amorphous layer is created at the same time as the oxide is removed by means of an ion beam. The amorphous layers on the surfaces of the substrates pre-treated and activated according to EP 3 161 855 B1 have a positive effect on the bond strength during bonding at room temperature. However, the amorphous residual layer in the bonded substrate stack has a disruptive effect by increasing the electrical resistance at the bonding interface. Furthermore, the amorphous residual layer after bonding can have a negative effect when the (multi-layer) substrate stack interacts with electromagnetic radiation. Relevant parameters here are, for example, the thickness and the different optical properties of the amorphous layer.

While the amorphous layer has a positive effect on the bonding process, the amorphous layer can therefore have a negative or disruptive effect on further process steps in the processing of the (multi-layer) substrate stack after the bonding process. As already mentioned, the residual amorphous layer at the bond interface can cause undesirable electrical resistance in the bonded substrate stack. As an additional layer in a bonded multilayer system, the amorphous layer can also interfere with further process steps. For example, the wavelength dependence of the refractive index of crystalline silicon (c-Si) and the amorphous silicon (a-Si) is different. This means that there can be a difference in the refractive index between crystalline and amorphous silicon during laser irradiation of the bonded multilayer system, for example during laser debonding. The parameters of a (bonded) substrate stack that are relevant for the interaction with electromagnetic radiation, in particular with laser beams, include the number of layers in the multilayer system, the thickness of all layers and the optical constants of all media. Therefore, the amorphous layer cannot be neglected.

Furthermore, very high levels of ion energy are required for oxide removal by atomization in order to remove matter from the surface of the substrate. As a result, ions are partially implanted into the substrate, damaging the layer in the vicinity of the surface. This damaged layer can usually be several nm thick, typically 5 to 10 nm and thicker. This damage can have a negative effect on the characteristics of the bonded joint in terms of electrical and optical parameters, making it undesirable and a problem in practice.

### SUMMARY

The task of the present invention is to provide a method and an apparatus for pre-treating a substrate surface, with which substrates can be bonded as far as possible without disturbing influences of the amorphous residual layer.

The task is solved by the disclosed method and the disclosed apparatus. Preferred embodiments can be found in the description, the dependent claims and the figures.

According to a first aspect of the present invention, a method for surface treatment of a substrate is intended, in particular as a preparatory step for a method for bonding the substrate to a further substrate, comprising:
providing the substrate with a bonding surface intended for bonding,
treatment of the substrate at least in a part of the bonding surface, forming an amorphous layer having a first thickness, preferably primary particle radiation being used to form the amorphous layer, and
layer thickness reduction of the amorphous layer, more preferably to a second thickness.

### BRIEF DESCRIPTION OF THE DRAWINGS

Further advantages, features and details of the invention will become apparent from the following description of preferred embodiments and from the drawings, in which:

FIG. 1 shows a flow chart for an exemplary method for producing a sub-nanometer thin amorphous layer on a substrate surface to be bonded;

FIG. 2 shows a time diagram having a thickness profile (layer thickness D) to illustrate the removal of the oxide layer (A) and formation of the amorphous layer (C) on the substrate surfaces (B) in the first process step (I) of the method according to the invention and reduction of the formed amorphous layer (C) in the second, multi-stage process step (II);

FIG. 3a shows a schematic ion beam voltage versus time diagram with a step-wise reduction of the ion beam voltage in the second process step; and

FIG. 3b shows a schematic ion beam voltage-time diagram with a continuous reduction of the ion beam voltage in the second process step.

In the figures, identical components or components with the same function are indicated with the same reference signs.

### DETAILED DESCRIPTION

Compared to the methods known from the prior art, it is additionally intended according to the invention to reduce the layer thickness of the amorphous layer. Reducing the layer thickness of the amorphous layer makes it possible to largely reduce the extent of the negtive effects of the amorphous layer. This allows the primary particle radiation to be used in an advantageous manner, which has proven to be particularly beneficial for the removal of oxides and thus for cleaning the substrate surfaces, especially in the area of the intended bonding surface. At the same time, the positive effect of the amorphous layer can also be used for the bonding process. Therefore, the combination of treatment of the substrate to form an amorphous layer on the one hand and layer thickness reduction on the other hand proves to be particularly advantageous.

In particular, it is intended that the treatment of the substrate prior to the layer thickness reduction of the amorphous layer serves to clean the bonding surface. In this process, the bonding surface is freed, at least in certain areas, from a natural and/or unnecessary oxide that is formed on a substrate surface. In particular, it is intended that the amorphous layer is formed by a phase transformation in which the composition of the crystalline substrate surface of the substrate provided is transformed in the treated area of the bonding surface. Thus, this procedure differs in particular from approaches in which an amorphous layer is specifically applied to the substrate surfaces. Instead, the primary particle radiation is used to convert the crystalline phase into an amorphous phase. Accordingly, a first kinetic energy of the primary particle radiation is set in such a way that a conversion into the amorphous phase is ensured. In this respect, explicit reference is made to the disclosure content of EP 3 161 855 B1. The substrate and the further substrate are more preferably bonded to each other via corresponding bonding surfaces.

While the formation of an amorphous layer is necessary for a better bonding result when bonding substrates at low temperatures, especially at room temperature, this amorphous layer can interfere with further process steps in the processing of the bonded multilayer system. In particular, the amorphous residual layer has a negative effect on the electrical properties of the bond interface. It therefore proves to be advantageous to further treat at least the bonding surface of the substrates, more preferably both substrates, in particular by dynamic atomization or a layer thickness reduction by means of particle radiation, so that the amorphous layer initially created by the pretreatment is removed again largely gently, in particular is reduced to a necessary minimum.

The substrates have at least one of the following (crystalline) materials:
Semiconductor materials such as Si, Ge,
III-V compound semiconductors such as GaAs, InP
II-VI compound semiconductors,
semiconductor alloys,
Oxides, in particular SiO2 and crystalline oxides of titanium,
Nitrides, in particular SiNx,
Metals such as Al, Cu, Au, Ti,
alloys,
ceramics,
carbides, in particular SiC

The substrates can have any shape, but are more preferably circular. For substrates, in particular the so-called wafers, the standard industrial diameters are 1 inch, 2 inch, 3 inch, 4 inch, 5 inch, 6 inch, 8 inch, 12 inch and 18 inch. However, a preferred embodiment can basically handle any substrate, regardless of its diameter.

More preferably, the particle radiation is ion radiation provided by an ion source or an ion gun. More preferably, a gas or a gas mixture is ionized for this purpose. It is most preferably intended that the layer thickness reduction, in particular in the form of atomization, is realized by means of particle radiation.

In a first process step in the sense of the method from EP 3 161 855 B1, the first kinetic energy of the ions is adjusted in such a way that they cause surface cleaning, in particular removal of the native oxide layer and amorphization, when they hit the substrate surfaces. The amorphization is limited in particular to the area near the surface of the substrates to be bonded together, preferably by selecting the process parameters temperature, pressure, ion energy and/or ion current density during the amorphization. Apart from the amorphized layer, the substrate material remains at least predominantly, preferably completely, crystalline. In a second process step, i.e. during the layer thickness reduction, the parameters relevant for the ion radiation, in particular ion energy and/or ion current density, are continuously or gradually reduced or changed in such a way that the amorphous layer created in the first process step is gently reduced further without other, collateral changes to the areas of the substrate close to the surface (i.e. implantation, further amorphization or atomization of the underlying substrate material itself).

Amorphization is preferably caused by particle collision with the substrate surfaces by the primary particle radiation. The particles are either charged or uncharged particles. Acceleration is more preferably carried out with charged particles, in particular ions, as charged particles are technically easier to accelerate.

When the ions penetrate into the area near the surface of the substrate, different interactions are caused between the ion and target atoms. The particle bombardment first causes the desorption of weakly bound adsorption layers, then the sputtering of foreign and reaction layers (for example oxides with thicknesses of 1 to 10 nm) and finally that of the substrate material itself.

Surface cleaning by means of primary particle radiation (sputtering) is an ion-induced emission of atoms, atom clusters or molecules from the substrate surfaces and is used for oxide removal. The sputtering yield depends, among other things, on the ion energy, the ion type, the ion incidence angle and the substrate material.

Radiation damagee and dislocations of substrate atoms occur in the substrate material mainly as a result of collision processes between the penetrating ions and the target atoms. The impact cascades triggered in the substrate and the layer create a high defect concentration, which can lead to amorphization. If an ion is fired at a solid with a sufficiently high power, in particular greater than 100 eV, it penetrates its surface and is subjected to interaction processes with the target material. For example, a point defect can occur if more than 25 eV is transferred to a lattice atom, depending on the material and the ion radiation. As the implantation dose increases, the individual defect areas begin to overlap and eventually lead to amorphization of the substrate material. If less than 25 eV is transferred to a lattice atom, this power is converted into phonon energy and causes an increase in temperature.

In the areas where the substrate material has been amorphized, there is no longer any long-range ordering of the atoms. The following parameters influence the transformation of the crystalline phase into an amorphous phase of the material, for example silicon after bombardment with heavy argon ions:
ion mass,
ion energy,
ion current strength or ion current density,
implantation dose,
ion incidence angle and
substrate temperature.

When atomizing with ion radiation, the power and current density of the bombarding ions can be varied independently of each other.

As part of the surface cleaning process, an amorphous surface layer forms after removal of the surface oxides due to radiation damages and dislocations and implantation of ions. The implantation of ions mainly takes place when high-energy ions are used. The implantation depends on the penetration depth of the injected ions into the substrate material, which depends on the ion energy and also the ion incidence angle. The substrate is located at a distance of 10 cm to 50 cm from the ion source's ion exit grid.

Particle bombardment with the primary particle radiation creates an amorphous layer in the existing crystalline base material of the substrate. In particular, the amorphization also causes a planarization of the substrate surfaces. The planarization of the surfaces, which has a positive effect on the bonding process, thus takes place in particular during amorphization, especially in addition to planarization by the application of force during the bonding process. The adjustment of the ions incidence angle of the primary particle radiation enables the ablation rate and thus the surface roughness to be controlled. The angle of incidence is therefore selected in particular to maximize amorphization, removal of impurities, especially oxides, and surface smoothing for the desired result. Amorphization also ensures greater mobility of the material at the interfaces. This means that any residual roughness can be better compensated for. In particular, any remaining gaps between the substrate surfaces can be closed. In particular, amorphization creates a thermodynamically metastable state at the substrate surfaces (bonding interface).

According to one embodiment of the invention, the angle of incidence between the substrate surfaces and the ion radiation is freely selectable and adjustable. The angle of incidence is defined as the angle between the substrate surfaces and the ion radiation. The angle of incidence is in particular between 0° and 90°, preferably between 20° and 70°, even more preferably between 30° and 60°. The angle of incidence of the ion radiation can be used to control the impact energy of the ions on the substrate surfaces.

Preferably, surface areas or bonding surfaces, in particular a contact side, preferably the entire surface, of both or at least one of the two substrates are amorphized in the surface cleaning and activation process prior to the bonding process. The surface cleaning and activation process can also be carried out on surface areas that are smaller than the substrate surfaces, in particular surface areas that are separated from each other.

The pre-treatment takes place in particular in a pre-treatment module that can be separated from the pre-fixing module and/or the bonding module, in particular by airlocks. In this module, surface cleaning is initially performed by particle bombardment and an amorphized substrate surface of the substrates is created. In particular, oxide removal, surface smoothing and amorphization are performed simultaneously.

More preferably, the amorphized layer is not created by a material applied by means of physical and/or chemical processes, but by a phase transformation of the substrate material. This makes it possible to completely dispense with the deposition of a material, particularly one that is undesirable or harmful.

According to a preferred embodiment of the invention, the amorphization is controlled by adjusting the first kinetic energy of the accelerated particles of the primary particle radiation, in particular the ions of a primary ion radiation. The first kinetic energy of the particles is set in particular between 1 eV and 100 keV, preferably between 25 eV and 50 keV, more preferably between 25 eV and 10 keV, most preferably between 25 eV and 1 keV. In a first embodiment, a low energy ion radiation such as an argon ion radiation has a power between 50 eV and 1 keV.

The current density (number of particles, in particular ions, per unit of time and area) is selected in particular between 0.1 mA/cm² and 10 mA/cm², preferably between 0.1 mA/cm² and 5 mA/cm², more preferably between 0.1 mA/cm² and 2 mA/cm².

The treatment duration of the treatment of the substrate to form an amorphous layer is selected in particular between 1 s and 200 s, preferably between 10 s and 200 s, even more preferably between 50 s and 200 s, most preferably between 100 s and 200 s. The treatment duration depends in particular on the process and material.

A first thickness of the amorphous layer immediately after creation in a substrate surface is in particular less than 100 nm, preferably less than 50 nm, more preferably less than 10 nm, most preferably less than 5 nm. The first thickness of the amorphous layer depends in particular on the process and material. Amorphization creates an amorphous layer a few nanometres thick in which the atoms are arranged in a random order. The random arrangement leads to a better bonding result, especially at comparatively low temperatures.

Preferably, it is intended that the primary particle radiation is realized with particles having a first kinetic energy to form the amorphous layer and that a secondary particle radiation is realized with particles having a second kinetic energy to reduce the layer thickness of the amorphous layer, the second kinetic energy being smaller than the first kinetic energy. It has been found that particle radiation can not only be used to convert the substrate surfaces into the amorphous phase to form the amorphous layer, but it is also possible to use particle radiation to realize the layer thickness reduction without damaging the substrate. It is also conceivable that the layer thickness reduction is performed mechanically and/or chemically and/or by means of laser light or the layer thickness reduction is supported by a mechanical and/or chemical ablation and/or an ablation caused by the action of laser light. In particular, it is more preferably intended that the particles with the first kinetic energy and the particles with the second kinetic energy are provided by the same particle source. This makes it possible to switch from a treatment for forming the amorphous phase to a layer thickness reduction without great effort.

In particular, a first and/or second kinetic energy is to be understood as the power of the particles that is to be assigned to the particles when they hit the substrate surfaces. If the particles are ions, the kinetic energy can be set particularly easily via the acceleration voltage in the ion source. However, it is also conceivable that the kinetic energy can be adjusted by a corresponding braking measure, for example downstream of an output from the ion source, or by extending the flight path.

Typical gases and/or gas mixtures that are used for surface cleaning, amorphization and subsequent dynamic atomization or layer thickness reduction using particle radiation include
atomic gases, in particular
   Ar, He, Kr, Ne, Xe,
molecular gases, in particular
   H₂, N₂, CO, CO₂,
gas mixtures, in particular
   forming gas FG (argon between 100% and 50%+hydrogen) and/or
   forming gas RFG (hydrogen between 100% and 50%+argon) and/or
   forming gas NFG (argon between 100% and 50%+nitrogen)

Atomic gases, preferably noble gases, in particular Ar, He, Kr, Ne, Xe, are more preferably used.

The treatment, in particular the cleaning, the removal of unwanted oxides and/or the amorphization, is more preferably carried out in a vacuum chamber as a process chamber. The vacuum chamber can be evacuated to a pressure of less than 1 bar, preferably less than 1 mbar, more preferably less than 10⁻³ mbar, using a suitable vacuum pump system. The vacuum chamber is preferably evacuated to the aforementioned pressure, more preferably completely, in particular before the ions are used for amorphization. The oxygen content in the process chamber is reduced to such an extent that renewed oxidation of the substrate surfaces is not possible.

For layer thickness reduction, the parameters relevant for the ion radiation, in particular ion energy and/or ion current strength, are gradually reduced or changed so that the amorphous layer created in the first process step is gently reduced without other, collateral changes to the areas of the substrate close to the surface, such as implantation, further amorphization or atomization of the substrate material itself.

The atomization rate is reduced by reducing the ion energy of the ion radiation. More preferably, the ion energy is lowered so that the amorphous layer can be gently ablated in a suitable time window. Removal still takes place via the physical atomization effect of the ions. The substrate remains in the same pre-treatment module and no further (wet) chemical and/or physical pre-treatment is necessary to activate the surface.

In the embodiment of atomization of the amorphous layer without active ion acceleration, the treatment duration for layer thickness reduction is selected in particular between 1 s and 1500 s, preferably between 20 s and 1200 s, even more preferably between 30 s and 1200 s.

In the embodiment of atomization of the amorphous layer with a low ion acceleration, the treatment duration is selected in particular between 1 s and 1200 s, preferably between 20 s and 900 s, even more preferably between 30 s and 600 s.

By using the ion gun or the ion radiation without ion acceleration, a correspondingly low ion energy and the lowest possible current density can be achieved. In addition to the low ion energy, the aim is also to achieve a short treatment duration. If the relevant parameters are optimally selected, the surface roughness or surface smoothing in the second process step does not change significantly.

The thickness of the amorphous layer created, but also the purity of the amorphous layer, influences the bond strength in the subsequent bonding process. According to EP 3 161 855 B1, the bond strength increases with increasing thickness of the amorphous layer. However, the thickness of the amorphous layer can be reduced for substrates with substrate surfaces with a very low average roughness. The average roughness of the substrate surfaces is in particular less than 10 nm, preferably less than 8 nm, even more preferably less than 6 nm, most preferably less than 4 nm, most preferably less than 1 nm.

In particular, it is intended that the second thickness of the amorphous layer of a substrate to be bonded is reduced to a necessary minimum.

The second thickness of the amorphous layer on the substrate is thus less than 15 nm, preferably less than 5 nm, even more preferably less than 2 nm, most preferably less than 0.5 nm, after further atomization of the substrate surfaces. In a preferred embodiment of the invention, the second thickness of the amorphous layer on the substrate after atomization of the substrate surfaces is between 0.1 nm and 2 nm. As a result, the greatly reduced amorphous layer can still positively influence the bonding strength when bonding the pre-treated substrates, wherein the second thickness of the residual amorphous layer has been reduced to such an extent that the bond interface layer shows a much lower electrical resistance in the bonded substrate stack.

Preferably, it is intended that a ratio of the second kinetic energy to the first kinetic energy is less than 0.1, preferably less than 0.05, and more preferably less than 0.01. It has been found to be particularly advantageous if the second kinetic energy is as small as possible, since in this way a particularly gentle removal of the amorphous material is possible, so that no further damage to the bonding surface occurs during the layer thickness reduction of the amorphous layer. In particular, the probability of renewed phase transformation into the amorphous phase or the implementation of ions into the substrate is reduced. It is also a finding that it is sufficient for the particles to hit the amorphous layer at their diffusion speed to cause the desired layer thickness reduction.

In particular, it is intended that the second kinetic energy of the secondary particle radiation is changed during the layer thickness reduction. In contrast, the first kinetic energy of the primary particle radiation is kept essentially constant. The reduction of the second kinetic energy proves to be advantageous because the probability of interaction with the substrate surfaces of the substrate is reduced as the layer thickness decreases. At the same time, a comparatively large amount of material is removed at the beginning of the layer thickness reduction, which proves to be advantageous in terms of the duration of the post-processing step that leads to the layer thickness reduction.

In a first embodiment, the layer thickness reduction of the amorphous layer is carried out in several steps, wherein the parameters of the ion radiation are changed several times, in particular reduced, such that the removal of the amorphous layer becomes smaller and smaller until the desired minimum layer thickness of the amorphous layer is achieved. In this first embodiment, the dynamic atomization of the amorphous layer is more preferably carried out in two to five steps, with the relevant ion beam parameters being changed in each step so that a smaller number of particles impact the substrate surfaces with less power.

Furthermore, it is more preferably intended that the second kinetic energy of the particles of the second particle radiation is continuously changed. In an exemplary embodiment, the parameters of the ion radiation are continuously changed, in particular reduced. More preferably, the Ion beam voltage is continuously reduced following the first process step for a gentle and controlled atomization of the amorphous layer until the required residual layer thickness is reached.

In particular, it is intended that the second kinetic energy of the particles of the second particle radiation is changed stepwise. In this embodiment, a layer thickness reduction is performed in the second process step, in particular an atomization of the amorphous layer with the ion radiation without ion acceleration (idle activation). The ion gun is operated in idle mode or with idle activation. The ions are not accelerated and the Ion beam voltage is gradually reduced in a first embodiment. In particular, the ion beam voltage is gradually reduced from 200 V to 50 V. For example, the Ion beam voltage is reduced in 50 V steps, more preferably in 20 V steps. In a second embodiment, the ion beam voltage is not reduced stepwise, but continuously from 200 V to 50 V. In the idle state, the plasma source or ion source is maintained and the potentials of the grids of the ion gun are of the same order of magnitude as the idle voltage after reduction of the Ion beam voltage.

The reduction of the ion energy and the reduction in the number of ions leaving the ion source in the open-circuit control considerably reduces the atomization rate, resulting in a very gentle reduction in the layer thickness of the amorphous layer.

In a further embodiment of the second process step, the ions are slightly accelerated and the ion beam voltage is gradually reduced from 200 V to 50 V in a first embodiment or continuously reduced from 200 V to 50 V in a supplementary embodiment. With a low acceleration of the ions, higher atomization rates can be achieved compared to the embodiment without active acceleration of the ions, so that the treatment duration can be shortened. This enables the treatment of thicker amorphous layers from the first process step, which can be shortened. In particular, the reduction of the amorphous layer thickness in the first process step, which is performed with much higher levels of ion energy, can be shortened, as the amorphous layer can be removed more gently and effectively in the second process step. The choice of embodiment is dependent on the substrate material and the ions used, as the layer thickness of the amorphous layer and the atomization rate can vary greatly.

In the preferred embodiment with a stepwise reduction, the Ion beam voltage is reduced in several steps, in particular in at least one step, preferably in at least two steps, even more preferably in at least three steps, most preferably in four steps. The threshold voltage at which atomization begins is between 20 V and 50 V depending on the substrate material and the ions used. In particular, the ion beam voltage is gradually reduced from 200 V to 50 V. The kinetic energy of the particles is low and lies in particular between 200 eV and 50 eV. In comparison, the surface cleaning and activation process in the first process step is performed with accelerated particles with a relatively high kinetic energy, in particular up to 1000 eV.

The acceleration of the ions can be controlled by individually adjusting the potentials of the grids of the ion gun, in particular of the suction grid and the acceleration grid. The aim of the present invention in the second process step is to provide an ion gun or to control it in such a way that a very low atomization of the amorphous layer can be achieved with a very low ion beam voltage and by exploiting the diffusion of the ions created.

The second kinetic energy of the particles of the secondary particle radiation is set in particular between 1 eV and 1 keV, preferably between 1 eV and 800 eV, even more preferably between 20 eV and 500 eV, most preferably between 20 eV and 300 eV, most preferably between 50 eV and 200 eV. A power between 50 eV and 200 eV has proven to be particularly advantageous. More preferably, the second kinetic energy changes over at least two thirds of the above intervals. This means that there is a comparatively large range of different second kinetic energies that are used to ablate the amorphous phase. This has proven to be advantageous in finding the best possible setting for layer thickness reduction, which can be realized quickly without causing damage to the substrate surface again.

It is more preferably intended for the second thickness to have a value that is less than 15 nm, preferably less than 5 nm and most preferably less than 2 nm or even less than 0.5 nm. With such small second thicknesses, in particular less than 2 nm, the positive properties of the amorphous layer can be advantageously utilized during bonding, i.e. bonding, while the amorphous layer is so thin that there is a sufficiently high probability that the amorphous layer will return to a crystalline phase during bonding. Advantageously, the overall substrate created from the bonding of the substrate and the further substrate then has only a low or even no amorphous content, which is disadvantageous with regard to individual physical properties of the overall substrate.

In particular, it is intended that the treatment to form the amorphous layer and the layer thickness reduction are performed in a common module. This makes it advantageously possible to realize the layer thickness reduction immediately after the formation of the amorphous phase, in particular without time-consuming transport of the substrate. In addition, the same properties can be used with advantage in the environment of the substrate, such as a temperature and/or a vacuum pressure in a treatment chamber of the apparatus for performing the method.

Preferably, it is intended that layer thickness reduction takes between 1 s and 1500 s, preferably between 20 s and 1200 s, more preferably between 30 s and 1200 s. It has been found that a corresponding layer thickness reduction can be realized comparatively quickly. The required period of time essentially depends on the second kinetic energy and on the second thickness to be set.

A further subject matter of the present invention is a method for bonding a substrate, which has been pre-treated with the method according to the invention, to a further substrate, which in particular has been pre-treated with the method according to the invention, wherein the substrate and the further substrate are bonded in a bonding process. All the advantages and properties of the above method can be transferred analogously to this method and vice versa. The substrate and the further substrate are connected or bonded to each other via respective bonding surfaces. The contacting of two substrate surfaces with very thin amorphous layers in the lower nm or sub-nanometer range leads to a better bond strength with the advantage of a vanishingly small amorphous layer at the substrate stack, which performs no substantial electrical resistance at the bonding interface due to the greatly reduced layer thickness.

In particular, it is intended that the second thickness is reduced to a third thickness during the bonding process. This has the advantage of avoiding further amorphous components in the overall substrate. In particular, it is intended that bonding parameters are set in such a way that a conversion of the amorphous phase into a crystalline phase is favored.

The total thickness of the amorphous layer in the substrate stack, formed from the substrate and the further substrate, is thus less than 30 nm after bonding, preferably less than 15 nm, even more preferably less than 5 nm, most preferably less than 2 nm, most preferably less than 1 nm.

In particular, a phase transformation from the amorphous state to the crystalline state can take place during and/or after the bonding and/or during the heat treatment during and/or after the bonding, so that the second thickness, i.e. a residual layer thickness of the amorphous layer, is further reduced to a third thickness. In a preferred embodiment, the aforementioned process parameters are selected such that the minimization of the layer thickness of the amorphous layer of the substrates to be bonded results in a complete conversion of the residual amorphous layer of the bonded substrate stack into the crystalline phase during and/or after bonding and/or during heat treatment.

After the pretreatment of at least one of the two substrate surfaces, preferably both substrate surfaces, the two substrates are aligned with respect to each other in an alignment module, preferably directly in the bonding chamber. The bonding of the pre-treated and aligned substrates takes place in the bonding chamber, whereby the bonding chamber is preferably integrally connected to the process chamber for amorphization and dynamic atomization in a cluster apparatus, and preferably can be transferred from the process chamber to the bonding chamber while maintaining constant evacuation.

In a preferred high vacuum environment, in particular <10-7 mbar, preferably <10-8 mbar, the polished and pre-treated substrate surfaces bond spontaneously and covalently by pure contacting without additional pressure or at least only very low pressure, in particular at room temperature. If necessary, the bonding process can be intensified by applying further force and/or temperature.

In particular, it is intended that the second thickness is adjusted in such a way that the amorphous layer present during bonding is converted into a crystalline phase. In particular, more than 30%, preferably more than 50% and more preferably more than 70% of the amorphous components of the amorphous layers are recycled into the crystalline phase. It is also conceivable that the second thickness is adjusted in such a way that the amorphous components are completely recycled into the crystalline phase.

It is most preferably intended that a sum of the second thickness of the substrate and the second thickness of the further substrate is less than 30 nm, preferably less than 15 nm, even more preferably less than 5 nm and most preferably less than 2 nm. It has been found with advantage that when setting the corresponding second thicknesses, no amorphous layer is formed on the overall substrate, which acts as a technical disturbance.

A further object of the present invention is an apparatus for performing a method according to the invention, comprising:
a particle source with which particles can be accelerated, and
substrate support for holding the substrate. All the properties and advantages described for the methods apply analogously to the apparatus and vice versa. Reference is made to publication EP 3 161 855 B1 with regard to the apparatus.

The invention relates in particular to a method and an apparatus for performing a dynamic sputtering process on a substrate surface to be bonded.

Preferably, an ion gun is provided and/or controlled in such a way that a low atomization of the amorphous layer can be achieved with a very low and decreasing Ion beam voltage and by exploiting the diffusion of the ions created, so that the amorphous layer is reduced to a minimum layer thickness without causing further damage to the substrate.

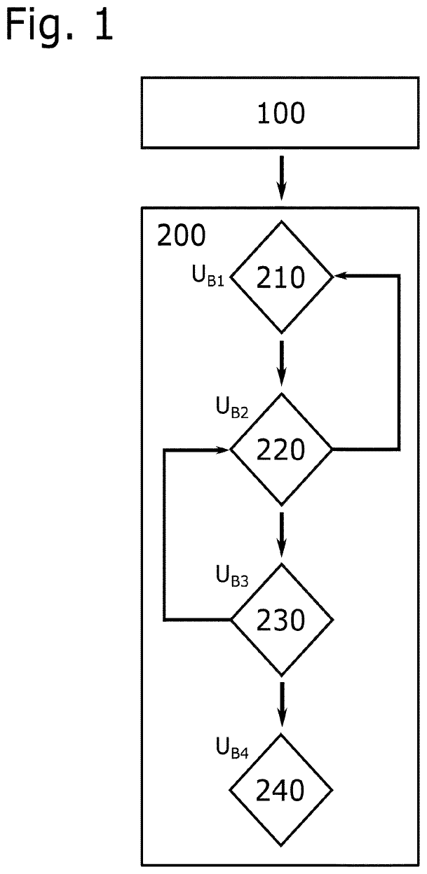

FIG. 1 shows a flow chart of an exemplary method for surface treatment in several steps according to a preferred embodiment of the present invention. In a first process step I 100, the power of low-energy ions is adjusted so that they cause surface cleaning, in particular removal of a native oxide layer and amorphization, in particular with phase transformation, when they hit on a substrate surface.

In a second process step II 200, the amorphous layer C created in the first process step I 100 is gradually reduced by dynamic atomization of the substrate surface with a very low ion acceleration or without active ion acceleration and with decreasing ion beam voltage, without substantial damages to the underlying substrate surface. The process steps I 100 and II 200 take place in the same module. In the second process step II 200, the Ion beam voltage is gradually reduced from a first voltage U_{B1} (first process step 210) to a fourth voltage U_{B4} (fourth process step 240) such that the layer thickness D of the amorphous layer C is gently reduced. The method steps 210 to 240 are preferably part of the second process step II 200. By switching off the idle activation, the diffusion of the ions created in the plasma source is utilized and no collateral changes take place in the areas of the substrate B close to the surface, such as implantation, further amorphization or atomization of the underlying crystalline substrate material itself. Due to the decreasing ion beam voltage U, the ion sputtering decreases so that less and less material is removed.

If required, for example in the second and third steps (220, 230), the parameters, such as setting the Ion beam voltage U or duration t of the treatment with a defined Ion beam voltage U, can be optimized by a control loop.

The second thickness D2 of the amorphous layer C on the substrate B after sputtering of the substrate surfaces is preferably less than 15 nm, more preferably less than 5 nm, even more preferably less than 2 nm, most preferably less than 1 nm, most preferably less than 0.5 nm.

In a preferred embodiment of the invention, the second thickness D2 of the amorphous layer C on the substrate B after dynamic atomization of the substrate surfaces is between 0.1 nm and 2 nm.

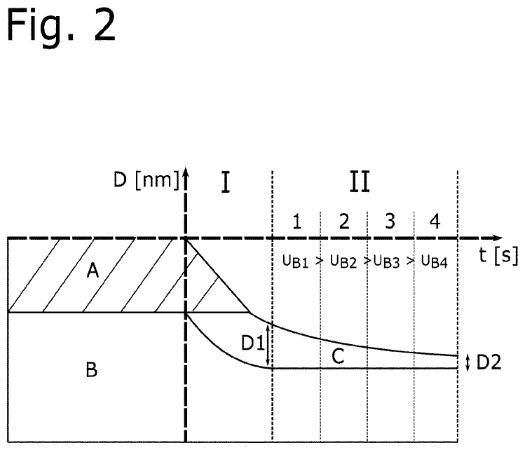

According to FIG. 2, in a first process step I 100, the natural oxide A is removed from the substrate surfaces of a substrate B by ion irradiation. In the first process step I 100, the thickness of the oxide layer A decreases until finally no oxide layer A is present. With increasing atomization and thus with increasing damage accumulation, an amorphous layer C is formed.

The ion source is, for example, a low-energy ion source. The ions created in the ionization chamber are extracted from the ion generation chamber using electrical fields. The ion radiation is then focused to the desired diameter, whereby a homogeneous current density is set in the beam. The ions can be slowed down to the desired power and refocused. The ion energies are, for example, between a few eV and 1 keV.

In a first embodiment, in the second process step II 200, atomization of the amorphous layer C of the pre-treated substrate surfaces is performed with the ion radiation without ion acceleration in the same module. The ion gun is operated in idle mode or with idle control and the diffusion of the ions from the ion source is utilized.

In a second embodiment of the second process step II200, the ions are accelerated slightly.

The acceleration of the ions is controlled by individually adjusting the potentials of the grids of the ion gun, in particular of the suction grid and the acceleration grid. The aim of the present invention in the second process step II 200 is to provide an ion gun or to control it in such a way that a very low atomization of the amorphous layer can be achieved with a very low ion beam voltage and by exploiting the diffusion of the ions created.

According to FIG. 2, the ion energy or the ion beam voltage U is reduced in several steps. FIG. 2 shows a reduction of the ion beam voltage in four steps 1 to 4. Due to the step-by-step reduction of the ion energy, the atomization rate is gradually reduced so that the layer thickness D of the amorphous layer C is reduced as much as possible and very gently. The layer thickness D of the amorphous layer C is reduced in the second process step II 200 according to FIG. 2 from a first thickness D1 to a second thickness D2, the so-called residual layer thickness D2. The ion beam voltage is gradually reduced from a first voltage (UB1) to a fourth voltage (UB4). The following applies: UB1>UB2>UB3>UB4. In particular, the Ion beam voltage U is gradually reduced from 200 V to 50 V.

In the embodiment of atomization of the amorphous layer C without active ion acceleration, the treatment duration t is selected in particular between 1 s and 1500 s, preferably between 20 s and 1200 s, even more preferably between 30 s and 1200 s.

In the embodiment of sputtering the amorphous layer C with a low ion acceleration, the treatment duration t is selected in particular between 1 s and 1200 s, preferably between 20 s and 900 s, even more preferably between 30 s and 600 s.

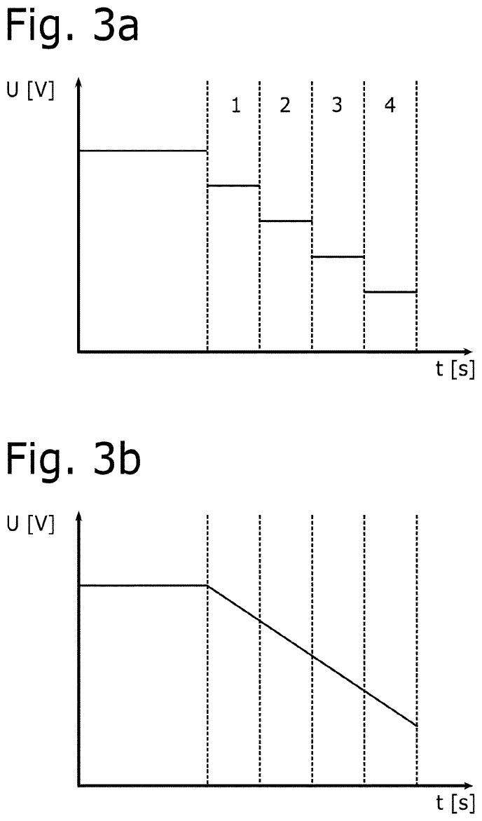

FIGS. 3a and 3b show the change in the Ion beam voltage in the course of the second process step II in different embodiments, one stepwise (see FIG. 3a) and one continuous (see FIG. 3b). The ion beam voltages U, U_{B1-B4} can be used to set corresponding second kinetic energies for the ions when they hit the substrate surfaces of substrate B.

### REFERENCE NUMBERS

A Oxide layer
B Substrate
C Amorphous layer
D Layer thickness
D1 First thickness
D2 Second thickness, residual layer thickness
U, U_{B1-B4} Ion beam voltages
t Time, treatment duration
100 First process step I, treatment
200 Second process step II, layer thickness reduction
210 First method step
220 Second method step
230 Third method step
240 Fourth method step V Volt
s Seconds

1-15. (canceled)

16. A method for surface treatment of a substrate (B), comprising:
providing the substrate (B) with a bonding surface intended for bonding,
treatment (100) of the substrate (B) at least in a subsection of the bonding surface to form an amorphous layer (C) with a first thickness (D1), and
layer thickness reduction (200) of the amorphous layer (C), wherein, for forming the amorphous layer (C), the primary particle radiation with particles comprising a first kinetic energy is realized and, for layer thickness reduction (200) of the amorphous layer (C) a secondary particle radiation with particles comprising a second kinetic energy is realized, wherein the second kinetic energy is smaller than the first kinetic energy.

17. The method according to claim 16, wherein a ratio of the second kinetic energy to the first kinetic energy is less than 0.1.

18. The method according to claim 16, wherein the second kinetic energy is changed during the layer thickness reduction (200).

19. The method according to claim 18, wherein the second kinetic energy of the particles of the secondary particle radiation is continuously changed.

20. The method according to claim 18, wherein the second kinetic energy of the particles of the secondary particle radiation is changed stepwise.

21. The method according to claim 16, wherein the layer thickness reduction (200) of the amorphous layer (C) reduces the layer thickness of the amorphous layer (C) to a second thickness (D2), and the second thickness (D2) has a value which is less than 15 nm.

22. The method according to claim 16, wherein the treatment for forming the amorphous layer (C) and the layer thickness reduction (200) are performed in a common module.

23. The method according to claim 16, wherein the second kinetic energy of the secondary particle radiation has a value between 1 eV and 1 keV.

24. The method according to claim 16, wherein the layer thickness reduction (200) lasts between 1 s and 1500 s.

25. A method for bonding a substrate (B) which has been pre-treated by the method according to claim 16 to a further substrate which has been pre-treated, wherein the substrate (B) and the further substrate are bonded with each other in a bonding process.

26. The method according to claim 25, wherein the second thickness (D2) of the substrate (B) and/or the second thickness (D2) of the further substrate is reduced to a third thickness during bonding in the bonding process.

27. The method according to claim 25, wherein a sum of the second thickness (D2) of the substrate (B) and the second thickness (D2) of the further substrate before bonding is less than 30 nm.
